(19) United States
(12) Patent Application Publication
(10) Pub. No.: US 2023/0221475 A1
(43) Pub. Date: Jul. 13, 2023

(54) TILED DISPLAY WITH OPTICAL BLUR SEAM

(71) Applicant: Corning Incorporated, (US)

(72) Inventors: Sean Matthew Garner, Elmira, NY (US); Daniel Aloysius Nolan, Corning, NY (US); Wageesha Senaratne, Horseheads, NY (US)

(21) Appl. No.: 17/768,643

(22) PCT Filed: Oct. 9, 2020
(86) PCT No.: PCT/US2020/054956

§ 371 Date: Apr. 13, 2022

Related U.S. Application Data
(60) Provisional application No. 62/926,730, filed on Oct. 28, 2019.

(51) Int. Cl. G02B 5/22

(52) U.S. Cl. CPC G02B 5/22

(57) ABSTRACT

A display device includes at least two adjacent display tiles having a seam therebetween, and an optical element at the seam to optically blur the seam between the adjacent display tiles, with each of the adjacent display tiles including a substrate, one or more light sources on a first surface of the substrate, and control electronics on a second surface of the substrate opposite the first surface.

### FIELD

This application claims the benefit of priority under 35 U.S.C. § 119 of U.S. Provisional Application Ser. No. 62/926730, filed on Oct. 28, 2019 the content of which is relied upon and incorporated herein by reference in its entirety.

The present disclosure relates generally to display tiles. More particularly, the present disclosure relates to optical blurring of a seam between adjacent display tiles of a tiled display.

### TECHNICAL BACKGROUND

Electronic displays may be used in numerous types of devices such as televisions, smart phones, tablet computers, automotive electronics, augmented reality devices, monitors, public information displays, and the like. A tiled display, in which display tiles are arranged next to each other such that pixels on adjacent display tiles continue at the same pitch as pixels within a display tile, may be used to achieve a “zero bezel” or “seamless tile” display. With a tiled display, a seam may exist between adjacent display tiles.

Accordingly, optical blurring of the seam between adjacent display tiles of a tiled display is disclosed herein.

### SUMMARY

Some embodiments of the present disclosure relate to a display device. The display device includes at least two adjacent display tiles having a seam therebetween, and an optical element at the seam to optically blur the seam between the adjacent display tiles, with each of the adjacent display tiles including a substrate, one or more light sources on a first surface of the substrate, and control electronics on a second surface of the substrate opposite the first surface.

Other embodiments of the present disclosure relate to a method of making a display device. The method includes positioning at least two display tiles adjacent to each other with a seam therebetween, and including an optical element at the seam to optically blur the seam between the adjacent display tiles, with each of the adjacent display tiles including a substrate, one or more light sources on a first surface of the substrate, and control electronics on a second surface of the substrate opposite the first surface.

Additional features and advantages will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate various embodiments described herein, and together with the description serve to explain the principles and operations of the claimed subject matter.

### BRIEF DESCRIPTION OF THE DRAWINGS

FIGS. 1A, 1B schematically depict front and back plan views, respectively, of an example of a display tile.

FIG. 1C schematically depicts a side view of an example of adjacent display tiles.

FIG. 2 schematically depicts a side view of an example of adjacent display tiles without an optically blurred seam.

FIG. 3 schematically depicts a side view of an example of adjacent display tiles with an optically blurred seam.

FIG. 4 schematically depicts a side view of an example of adjacent display tiles with an optically blurred seam.

FIG. 5 schematically depicts a side view of an example of adjacent display tiles with an optically blurred seam.

FIG. 6 schematically depicts a side view of an example of adjacent display tiles with an optically blurred seam.

FIG. 7 schematically depicts a side view of an example of adjacent display tiles with an optically blurred seam.

FIG. 8 schematically depicts a side view of an example of adjacent display tiles with an optically blurred seam.

FIG. 9 schematically depicts a side view of an example of adjacent display tiles with an optically blurred seam.

### DETAILED DESCRIPTION

Reference will now be made in detail to embodiments of the present disclosure, examples of which are illustrated in the accompanying drawings. Whenever possible, the same reference numerals will be used throughout the drawings to refer to the same or like parts. However, this disclosure may be embodied in many different forms and should not be construed as limited to the embodiments set forth herein.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein (for example, up, down, right, left, front, back, top, bottom, vertical, horizontal) are made only with reference to the figures as drawn and are not intended to imply absolute orientation.

Unless otherwise expressly stated, it is in no way intended that any method set forth herein be construed as requiring that its steps be performed in a specific order, nor that with any apparatus, specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an,” and “the” include plural references unless the context clearly dictates otherwise. Thus, for example, reference to “a” component includes aspects having two or more such components, unless the context clearly indicates otherwise.

As disclosed herein, a display device and a method of making a display device optically blurs a seam between adjacent display tiles of a tiled display so as to minimize or eliminate optical defects resulting from the seam. The seam between adjacent display tiles may include, for example, a spacing or gap formed by, at, or between opposing edges of adjacent display tiles, or may include, for example, a point, line, position, region, or area where opposing edges of adjacent display tiles meet or physically contact each other. As disclosed herein, the seam between adjacent display tiles may be optically blurred, for example, by scattering and/or absorbing light at the seam. As such, in examples, light from and/or at the seam may be optically blended or dispersed.

Accordingly, a display device and a method of making a display device with optical blurring of a seam between adjacent display tiles of a tiled display, as disclosed herein, provides an optical solution for maximizing a signal/noise ratio observed by a viewer at the seam by attempting to match a contrast ratio of pixels at the seam with a contrast ratio of pixels at or near a center of a display tile, where the signal is the display image and the noise is the result of stray light from pixel emitters or ambient sources.

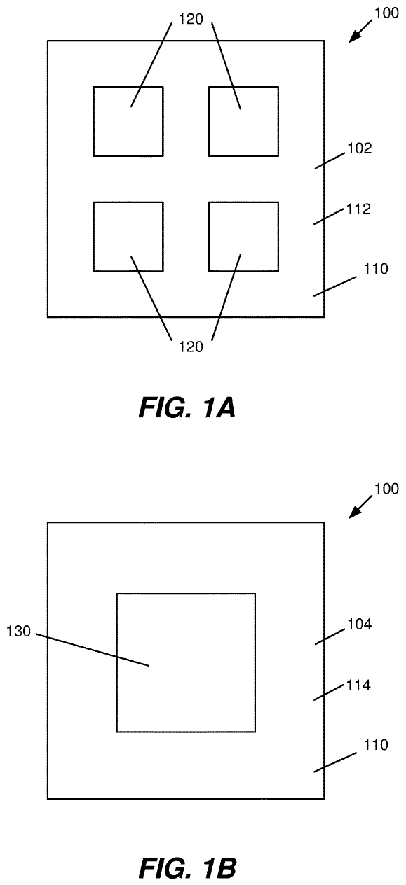

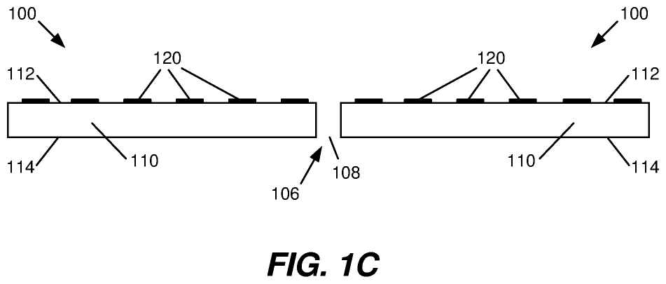

Referring to FIGS. 1A, 1B, an exemplary display tile 100 is schematically depicted. More specifically, FIG. 1A schematically depicts a front plan view of an example of display tile 100, and FIG. 1B schematically depicts a back plan view of an example of display tile 100. Display tile 100 includes a substrate 110, one or more light sources 120, and drive circuitry or control electronics 130.

In the depicted example, substrate 110 has a first surface 112 (FIG. 1A) and a second surface 114 (FIG. 1B) opposite first surface 112, with light sources 120 provided on first surface 112 and control electronics 130 provided on second surface 114. In examples, first surface 112 represents a front or first side 102 of display tile 100, and second surface 114 represents a back or second side 104 of display tile 100. This configuration is for a top emission display tile. Other configurations for a bottom emission display tile are also possible where light sources 120 are provided on second surface 114 (with control electronics 130).

Substrate 110 may be formed of glass, glass ceramic, ceramic, or polymer material, or a composite material including different combinations of such materials in a layered or mixture format. In examples, substrate 110 may have a thickness between 0.005 mm and 2 mm, including, more specifically, a thickness between 0.01 mm and 1 mm, between 0.01 mm and 0.7 mm, between 0.05 mm and 0.6 mm, between 0.1 mm and 0.5 mm, or between 0.2 mm and 0.4 mm. In examples, substrate 110 may be rectangular in shape, as illustrated in FIGS. 1A and 1B, or may be of another regular or irregular geometric shape.

Light sources 120 may be arranged, for example, in an array including any number of rows and columns, or other patterns. Each light source 120 is electrically coupled to drive circuitry, such as drive circuitry or control electronics 130, for driving or controlling operation of each light source 120. Control electronics 130 may include, for example, drive ICs, thin film transistors, microDriver ICs, and/or electrical interconnects. Although illustrated as being provided on second surface 114, in other examples, control electronics 130 (or components thereof) may be provided on first surface 112 (with light sources 120). Each light source 120 may include, for example, a light emitting diode (LED), a microLED, an organic light emitting diode (OLED), or other suitable light source or light modulator, such as a mirror or light valve.

FIG. 1C schematically depicts a side view of an example of adjacent display tiles 100, 100. More specifically, as depicted in the example of FIG. 1C, display tiles 100, 100 each include substrate 110 having first surface 112 and second surface 114 opposite first surface 112, with light sources 120 provided on first surface 112 and control electronics 130 (FIG. 1B) provided on second surface 114. In other examples, the surface on which light sources 120 and/or control electronics 130 are provided may be varied. In the depicted example, display tiles 100, 100 are arranged next to each other such that a seam 106 exists between display tiles 100, 100. In examples, a gap 108 may exist at seam 106 between adjacent display tiles 100, 100. As such, in examples, seam 106 includes gap 108 between adjacent display tiles 100, 100.

In examples, substrate 110 may have edges with square corners as shown in FIG. 1C. In other examples, edges of substrate 110 may be rounded, chamfered, or have some other cross-sectional shape that is symmetric from frontside and backside or asymmetric. In examples, substrate 110 may be substantially flat or have a radius of curvature of <3 m, <1 m, <0.5 m, or <0.2 m. In examples, gap 108 may have a width of <500 μm, <200 μm, <100 μm, <50 μm, or <20 μm. In examples, a ratio of a thickness of substrate 110 to gap 108 may be between 1:1 to 50,000:1, between 0.1:1 to 10,000:1, between 0.1:1 to 1000:1, between 1:1 to 100:1, or between 1:1 to 10:1. In examples, a ratio of a pixel pitch of display tile 100 (spacing between light sources 120) to gap 108 may be between 1:1 to 50:1, between 1:1 to 20:1, or between 5:1 to 10:1.

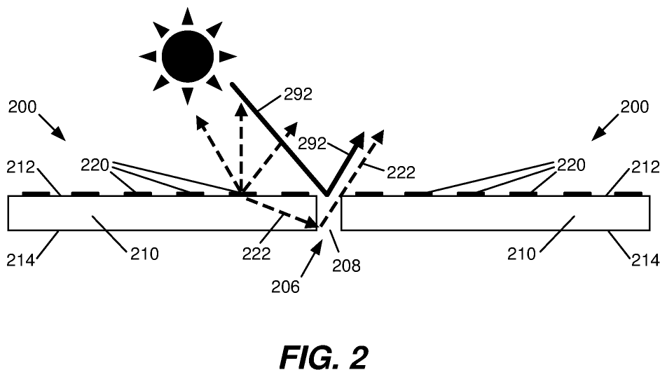

FIG. 2 schematically depicts a side view of an example of adjacent display tiles 200, 200 without an optically blurred seam. More specifically, as depicted in the example of FIG. 2, display tiles 200, 200, each as examples of display tile 100, include a substrate 210 having a first surface 212 and a second surface 214 opposite first surface 212, with light sources 220 provided on first surface 212 and control electronics, such as control electronics 130 (FIG. 1 B), provided on second surface 214. In other examples, light sources 220 and/or control electronics may be provided on other surfaces. In the depicted example, display tiles 200, 200 are arranged next to each other such that a seam 206 exists between display tiles 200, 200. In examples, a gap 208 may exist at seam 206 between adjacent display tiles 200, 200. As such, in examples, seam 206 includes gap 208 between adjacent display tiles 200, 200.

As schematically depicted in the example of FIG. 2, without optical blurring of seam 206, light from an external source, such as ambient light 292, is reflected from seam 206 including, more specifically, from gap 208 between adjacent display tiles 200, 200. In addition, light from an internal source, such as light 222 from a light source 220, is reflected from seam 206 including, more specifically, from gap 208 between adjacent display tiles 200, 200. Reflection of light from seam 206 including, more specifically, from gap 208 between adjacent display tiles 200, 200 includes reflection of light from an edge or edge interface (e.g., opposing edges) of display tiles 200, 200.

With light reflected from seam 206 including, more specifically, from gap 208 between adjacent display tiles 200, 200, the amount of light reflected or scattered from gap 208 is different than the amount of light reflected or scattered from display tiles 200, 200. As such, light reflected from seam 206 including, more specifically, from gap 208 between adjacent display tiles 200, 200 may result in optical defects, such as degraded contrast ratio, bright or dark spots or lines, and/or image distortion. For example, light reflected from seam 206 including, more specifically, from gap 208 between adjacent display tiles 200, 200 may produce stray light which may result in degraded image quality or degraded viewing experience of the display tiles. Specifically, ambient light or light produced from light sources 220 may be reflected or transmitted differently at seam 206, including from gap 208, as compared to display tiles 200, 200. This difference in reflected or transmitted light may produce an optical intensity variation across the tiled display, as observed by a viewer.

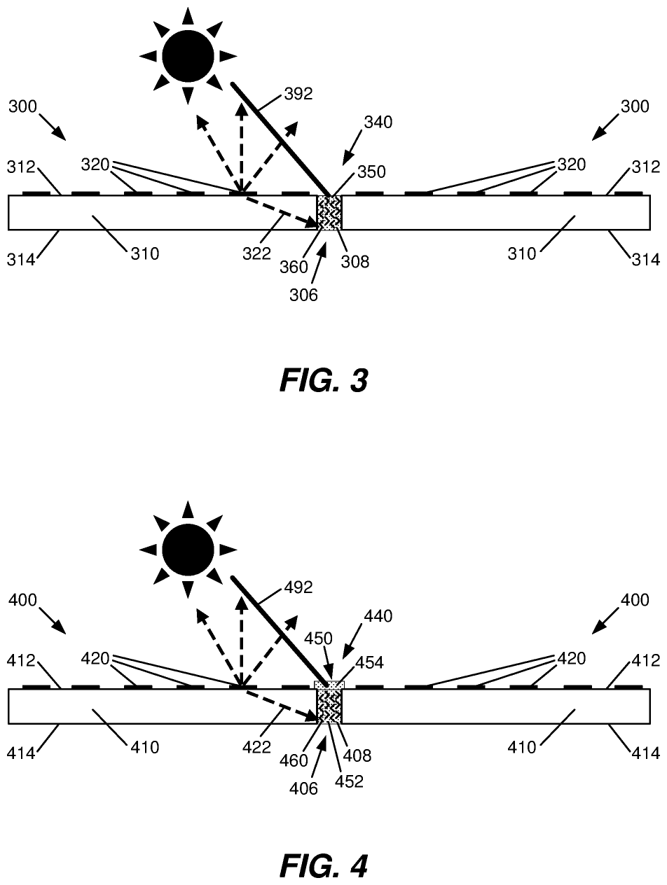

FIG. 3 schematically depicts a side view of an example of adjacent display tiles 300, 300 with an optically blurred seam. More specifically, as depicted in the example of FIG. 3, display tiles 300, 300, each as examples of display tile 100, include a substrate 310 having a first surface 312 and a second surface 314 opposite first surface 312, with light sources 320 provided on first surface 312 and control electronics, such as control electronics 130 (FIG. 1B), provided on second surface 314. In other examples, light sources 320 and/or control electronics may be provided on other surfaces. In the depicted example, display tiles 300, 300 are arranged next to each other such that a seam 306 exists between display tiles 300, 300. In examples, a gap 308 may exist at seam 306 between adjacent display tiles 300, 300. As such, in examples, seam 306 includes gap 308 between adjacent display tiles 300, 300.

In one example, as depicted in FIG. 3, seam 306 including, more specifically, gap 308 between adjacent display tiles 300, 300, is optically blurred by an optical element 340 at seam 306 including, more specifically, at gap 308 between adjacent display tiles 300, 300. Optical element 340 optically blurs seam 306 between adjacent display tiles 300, 300, for example, by scattering and/or absorbing light at seam 306. As such, in examples, optical element 340 optically blends or disperses light from and/or at seam 306. In addition, in examples, optical element 340 may provide optical matching between adjacent display tiles 300, 300. In the depicted example, optical element 340 is within gap 308 between adjacent display tiles 300, 300.

In examples, optical element 340 includes optical material 350 at seam 306 including, more specifically, within gap 308 between adjacent display tiles 300, 300. Optical material 350 may include, for example, an optical or light scattering material, an optical or light absorbing material, and/or an optical matching material. Examples of optical material 350 include an optical scattering material, such as an optical adhesive filled with nanometer to micrometer sized particles; or an optical absorbing material, such as a material that contains carbon black; or an optical matching material, such as an index matching optical adhesive. In examples, optical material 350 may have a substantially uniform optical response (transmission, scattering, absorption) in an optical wavelength range of 400 nm to 800 nm. In other examples, optical material 350 may have a varying optical response in an optical wavelength range of 400 nm to 800 nm.

In the depicted example, optical material 350 substantially fills gap 308 between adjacent display tiles 300, 300. More specifically, in the depicted example, optical material 350 contacts and extends between adjacent display tiles 300, 300 so as to occupy substantially all the space between adjacent display tiles 300, 300.

In examples, optical element 340 includes optical features 360 at seam 306 including, more specifically, within gap 308 between adjacent display tiles 300, 300. Optical features 360 may include, for example, optical or light scattering features and/or optical or light absorbing features. Examples of optical features 360 include roughness, prisms, lenticulars, or other physical structures. Optical features 360 may be provided, for example, at or on a surface or interface of optical element 340 or within its bulk.

In the depicted example, optical features 360 are supported by optical material 350 at seam 306. More specifically, in the depicted example, optical features 360 are supported by optical material 350 as provided within gap 308 between adjacent display tiles 300, 300.

As schematically depicted in the example of FIG. 3, with optical blurring of seam 306 by optical element 340, including optical material 350 and/or optical features 360, light from an external source, such as ambient light 392, is scattered and/or absorbed at seam 306 including, more specifically, at gap 308 between adjacent display tiles 300, 300. In addition, light from an internal source, such as light 322 from a light source 320, is scattered and/or absorbed at seam 306 including, more specifically, at gap 308 between adjacent display tiles 300, 300. By scattering and/or absorbing light at seam 306 including, more specifically, at gap 308 between adjacent display tiles 300, 300, optical defects resulting from seam 306 including, more specifically, from gap 308 between adjacent display tiles 300, 300 may be minimized or eliminated. Specifically, ambient light or light produced from light sources 320 may be reflected or transmitted similarly at seam 306, including from gap 308, as compared to display tiles 300, 300. As such, in examples, optical element 340 may provide optical matching between adjacent display tiles 300, 300.

FIG. 4 schematically depicts a side view of an example of adjacent display tiles 400, 400 with an optically blurred seam. More specifically, as depicted in the example of FIG. 4, display tiles 400, 400, each as examples of display tile 100, include a substrate 410 having a first surface 412 and a second surface 414 opposite first surface 412, with light sources 420 provided on first surface 412 and control electronics, such as control electronics 130 (FIG. 1 B), provided on second surface 414. In other examples, light sources 420 and/or control electronics may be provided on other surfaces. In the depicted example, display tiles 400, 400 are arranged next to each other such that a seam 406 exists between display tiles 400, 400. In examples, a gap 408 may exist at seam 406 between adjacent display tiles 400, 400. As such, in examples, seam 406 includes gap 408 between adjacent display tiles 400,

In one example, as depicted in FIG. 4, seam 406 including, more specifically, gap 408 between adjacent display tiles 400, 400, is optically blurred by an optical element 440 at seam 406 including, more specifically, at gap 408 between adjacent display tiles 400, 400. Optical element 440 optically blurs seam 406 between adjacent display tiles 400, 400, for example, by scattering and/or absorbing light at seam 406. As such, in examples, optical element 440 optically blends or disperses light from and/or at seam 406. In addition, in examples, optical element 440 may provide optical matching between adjacent display tiles 400, 400. In the depicted example, optical element 440 is within and across gap 408 between adjacent display tiles 400, 400.

In examples, optical element 440 includes optical material 450 at seam 406 including, more specifically, within and across gap 408 between adjacent display tiles 400, 400. Optical material 450 may include, for example, an optical or light scattering material, an optical or light absorbing material, and/or an optical matching material. Examples of optical material 450 include an optical scattering material, such as an optical adhesive filled with nanometer to micrometer sized particles; or an optical absorbing material, such as a material that contains carbon black; or an optical matching material, such as an index matching optical adhesive. In examples, optical material 450 may have a substantially uniform optical response (transmission, scattering, absorption) in an optical wavelength range of 400 nm to 800 nm. In other examples, optical material 450 may have a varying optical response in an optical wavelength range of 400 nm to 800 nm.

In the depicted example, optical material 450 includes optical material 452 substantially filling gap 408 between adjacent display tiles 400, 400 and optical material 454 extended across (or over) gap 408 between adjacent display tiles 400, 400. Optical material 452 and optical material 454 may include the same material or different materials.

In examples, optical element 440 includes optical features 460 at seam 406 including, more specifically, within gap 408 between adjacent display tiles 400, 400. Optical features 460 may include, for example, optical or light scattering features and/or optical or light absorbing features. Examples of optical features 460 include roughness, prisms, lenticulars, or other physical structures. Optical features 460 may be provided, for example, at or on a surface or interface of optical element 440 or within its bulk.

In the depicted example, optical features 460 are supported by optical material 450 at seam 406. More specifically, in the depicted example, optical features 460 are supported by optical material 452 as provided within gap 408 between adjacent display tiles 400, 400.

As schematically depicted in the example of FIG. 4, with optical blurring of seam 406 by optical element 440, including optical material 450 and/or optical features 460, light from an external source, such as ambient light 492, is scattered and/or absorbed at seam 406 including, more specifically, at gap 408 between adjacent display tiles 400, 400. In addition, light from an internal source, such as light 422 from a light source 420, is scattered and/or absorbed at seam 406 including, more specifically, at gap 408 between adjacent display tiles 400, 400. By scattering and/or absorbing light at seam 406 including, more specifically, at gap 408 between adjacent display tiles 400, 400, optical defects resulting from seam 406 including, more specifically, from gap 408 between adjacent display tiles 400, 400 may be minimized or eliminated. Specifically, ambient light or light produced from light sources 420 may be reflected or transmitted similarly at seam 406, including from gap 408, as compared to display tiles 400, 400. As such, in examples, optical element 440 may provide optical matching between adjacent display tiles 400, 400.

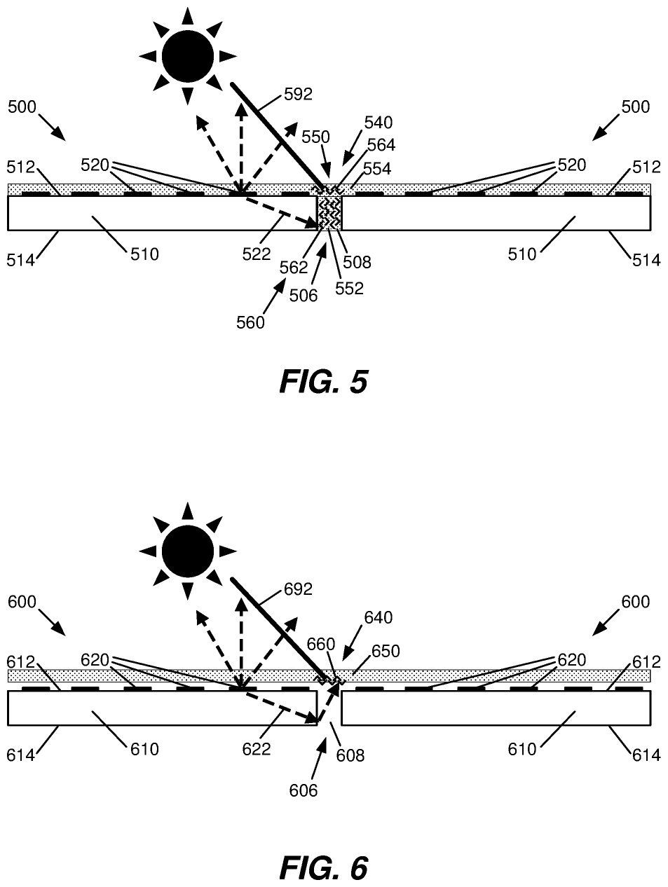

FIG. 5 schematically depicts a side view of an example of adjacent display tiles 500, 500 with an optically blurred seam. More specifically, as depicted in the example of FIG. 5, display tiles 500, 500, each as examples of display tile 100, include a substrate 510 having a first surface 512 and a second surface 514 opposite first surface 512, with light sources 520 provided on first surface 512 and control electronics, such as control electronics 130 (FIG. 1 B), provided on second surface 514. In other examples, light sources 520 and/or control electronics may be provided on other surfaces. In the depicted example, display tiles 500, 500 are arranged next to each other such that a seam 506 exists between display tiles 500, 500. In examples, a gap 508 may exist at seam 506 between adjacent display tiles 500, 500. As such, in examples, seam 506 includes gap 508 between adjacent display tiles 500, 500.

In one example, as depicted in FIG. 5, seam 506 including, more specifically, gap 508 between adjacent display tiles 500, 500, is optically blurred by an optical element 540 at seam 506 including, more specifically, at gap 508 between adjacent display tiles 500, 500. Optical element 540 optically blurs seam 506 between adjacent display tiles 500, 500, for example, by scattering and/or absorbing light at seam 506. As such, in examples, optical element 540 optically blends or disperses light from and/or at seam 506. In addition, in examples, optical element 540 may provide optical matching between adjacent display tiles 500, 500. In the depicted example, optical element 540 is within and across gap 508 between adjacent display tiles 500, 500.

In examples, optical element 540 includes optical material 550 at seam 506 including, more specifically, within and across gap 508 between adjacent display tiles 500, 500. Optical material 550 may include, for example, an optical or light scattering material, an optical or light absorbing material, and/or an optical matching material. Examples of optical material 550 include an optical scattering material, such as an optical adhesive filled with nanometer to micrometer sized particles; or an optical absorbing material, such as a material that contains carbon black; or an optical matching material, such as an index matching optical adhesive. In examples, optical material 550 may have a substantially uniform optical response (transmission, scattering, absorption) in an optical wavelength range of 400 nm to 800 nm. In other examples, optical material 550 may have a varying optical response in an optical wavelength range of 400 nm to 800 nm.

In the depicted example, optical material 550 includes optical material 552 substantially filling gap 508 between adjacent display tiles 500, 500 and optical material 554 extended across (or over) gap 508 between adjacent display tiles 500, 500. Optical material 552 and optical material 554 may include the same material or different materials. In examples, optical material 554 includes a cover glass or a layer of polymer material extended over light sources 520 of adjacent display tiles 500, 500 such that optical material 554 contacts first surface 512 of adjacent display tiles 500, 500. Examples of the cover glass include ion exchanged glass, chemically strengthened glass, such as Corning® Gorilla® glass from Corning Incorporated, soda lime glass, drawn or rolled or float glass sheet, or alkali-free glass.

In examples, optical element 540 includes optical features 560 at seam 506 including, more specifically, within gap 508 between adjacent display tiles 500, 500 and across gap 508 between adjacent display tiles 500, 500. Optical features 560 may include, for example, optical or light scattering features and/or optical or light absorbing features. Examples of optical features 560 include roughness, prisms, lenticulars, or other physical structures. Optical features 560 may be provided, for example, at or on a surface or interface of optical element 540 or within its bulk.

In the depicted example, optical features 560 are supported by optical material 550 at seam 506. More specifically, in the depicted example, optical features 560 include optical features 562 supported by optical material 552 as provided within gap 508 between adjacent display tiles 500, 500, and optical features 564 supported by optical material 554 as provided across (or over) gap 508 between adjacent display tiles 500, 500. As such, optical features 562 are provided within gap 508 between adjacent display tiles 500, 500 and optical features 564 are provided across (or at) gap 508 between adjacent display tiles 500, 500. Optical features 562 and optical features 564 may include the same or different features.

As schematically depicted in the example of FIG. 5, with optical blurring of seam 506 by optical element 540, including optical material 550 and/or optical features 560, light from an external source, such as ambient light 592, is scattered and/or absorbed at seam 506 including, more specifically, at gap 508 between adjacent display tiles 500, 500. In addition, light from an internal source, such as light 522 from a light source 520, is scattered and/or absorbed at seam 506 including, more specifically, at gap 508 between adjacent display tiles 500, 500. By scattering and/or absorbing light at seam 506 including, more specifically, at gap 508 between adjacent display tiles 500, 500, optical defects resulting from seam 506 including, more specifically, from gap 508 between adjacent display tiles 500, 500 may be minimized or eliminated. Specifically, ambient light or light produced from light sources 520 may be reflected or transmitted similarly at seam 506, including from gap 508, as compared to display tiles 500, 500. As such, in examples, optical element 540 may provide optical matching between adjacent display tiles 500, 500.

FIG. 6 schematically depicts a side view of an example of adjacent display tiles 600, 600 with an optically blurred seam. More specifically, as depicted in the example of FIG. 6, display tiles 600, 600, each as examples of display tile 100, include a substrate 610 having a first surface 612 and a second surface 614 opposite first surface 612, with light sources 620 provided on first surface 612 and control electronics, such as control electronics 130 (FIG. 1 B), provided on second surface 614. In other examples, light sources 620 and/or control electronics may be provided on other surfaces. In the depicted example, display tiles 600, 600 are arranged next to each other such that a seam 606 exists between display tiles 600, 600. In examples, a gap 608 may exist at seam 606 between adjacent display tiles 600, 600. As such, in examples, seam 606 includes gap 608 between adjacent display tiles 600, 600.

In one example, as depicted in FIG. 6, seam 606 including, more specifically, gap 608 between adjacent display tiles 600, 600, is optically blurred by an optical element 640 at seam 606 including, more specifically, at gap 608 between adjacent display tiles 600, 600. Optical element 640 optically blurs seam 606 between adjacent display tiles 600, 600, for example, by scattering and/or absorbing light at seam 606. As such, in examples, optical element 640 optically blends or disperses light from and/or at seam 606. In addition, in examples, optical element 640 may provide optical matching between adjacent display tiles 600, 600. In the depicted example, optical element 640 is across gap 608 between adjacent display tiles 600,

In examples, optical element 640 includes optical material 650 at seam 606 including, more specifically, across gap 608 between adjacent display tiles 600, 600. Optical material 650 may include, for example, an optical or light scattering material, an optical or light absorbing material, and/or an optical matching material. Examples of optical material 650 include an optical scattering material, such as an optical adhesive filled with nanometer to micrometer sized particles; or an optical absorbing material, such as a material that contains carbon black; or an optical matching material, such as an index matching optical adhesive. In examples, optical material 650 may have a substantially uniform optical response (transmission, scattering, absorption) in an optical wavelength range of 400 nm to 800 nm. In other examples, optical material 650 may have a varying optical response in an optical wavelength range of 400 nm to 800 nm.

In the depicted example, optical material 650 extends across (or over) gap 608 between adjacent display tiles 600, 600. In examples, optical material 650 includes a cover glass or a layer of polymer material extended over light sources 620 of adjacent display tiles 600, 600 such that optical material 650 is spaced from first surface 612 of adjacent display tiles 600, 600. Examples of the cover glass include ion exchanged glass, chemically strengthened glass, such as Corning® Gorilla® glass from Corning Incorporated, soda lime glass, drawn or rolled or float glass sheet, or alkali-free glass.

In examples, optical element 640 includes optical features 660 at seam 606 including, more specifically, across gap 608 between adjacent display tiles 600, 600. Optical features 660 may include, for example, optical or light scattering features and/or optical or light absorbing features. Examples of optical features 660 include roughness, prisms, lenticulars, or other physical structures. Optical features 660 may be provided, for example, at or on a surface or interface of optical element 640 or within its bulk.

In the depicted example, optical features 660 are supported by optical material 650 at seam 606. More specifically, in the depicted example, optical features 660 are supported by optical material 650 as provided across (or over) gap 608 between adjacent display tiles 600, 600. As such, optical features 660 are provided across (or at) gap 608 between adjacent display tiles 600, 600.

As schematically depicted in the example of FIG. 6, with optical blurring of seam 606 by optical element 640, including optical material 650 and/or optical features 660, light from an external source, such as ambient light 692, is scattered and/or absorbed at seam 606 including, more specifically, at gap 608 between adjacent display tiles 600, 600. In addition, light from an internal source, such as light 622 from a light source 620, is scattered and/or absorbed at seam 606 including, more specifically, at gap 608 between adjacent display tiles 600, 600. By scattering and/or absorbing light at seam 606 including, more specifically, at gap 608 between adjacent display tiles 600, 600, optical defects resulting from seam 606 including, more specifically, from gap 608 between adjacent display tiles 600, 600 may be minimized or eliminated. Specifically, ambient light or light produced from light sources 620 may be reflected or transmitted similarly at seam 606, including from gap 608, as compared to display tiles 600, 600. As such, in examples, optical element 640 may provide optical matching between adjacent display tiles 600, 600.

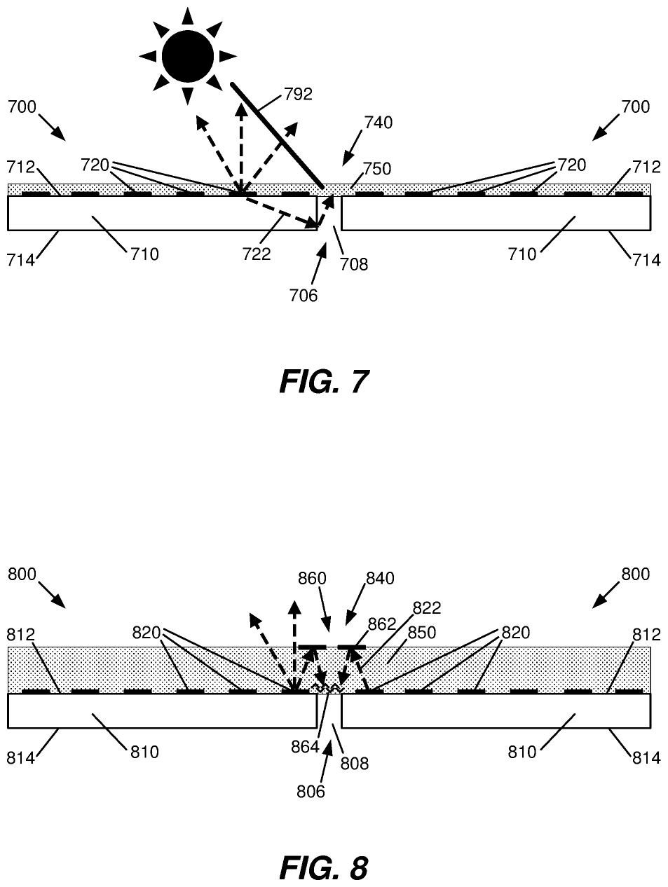

FIG. 7 schematically depicts a side view of an example of adjacent display tiles 700, 700 with an optically blurred seam. More specifically, as depicted in the example of FIG. 7, display tiles 700, 700, each as examples of display tile 100, include a substrate 710 having a first surface 712 and a second surface 714 opposite first surface 712, with light sources 720 provided on first surface 712 and control electronics, such as control electronics 130 (FIG. 1B), provided on second surface 714. In other examples, light sources 720 and/or control electronics may be provided on other surfaces. In the depicted example, display tiles 700, 700 are arranged next to each other such that a seam 706 exists between display tiles 700, 700. In examples, a gap 708 may exist at seam 706 between adjacent display tiles 700, 700. As such, in examples, seam 706 includes gap 708 between adjacent display tiles 700, 700.

In one example, as depicted in FIG. 7, seam 706 including, more specifically, gap 708 between adjacent display tiles 700, 700, is optically blurred by an optical element 740 at seam 706 including, more specifically, at gap 708 between adjacent display tiles 700, 700. Optical element 740 optically blurs seam 706 between adjacent display tiles 700, 700, for example, by scattering and/or absorbing light at seam 706. As such, in examples, optical element 740 optically blends or disperses light from and/or at seam 706. In addition, in examples, optical element 740 may provide optical matching between adjacent display tiles 700, 700. In the depicted example, optical element 740 is across gap 708 between adjacent display tiles 700, 700.

In examples, optical element 740 includes optical material 750 at seam 706 including, more specifically, across gap 708 between adjacent display tiles 700, 700. Optical material 750 may include, for example, an optical or light scattering material, an optical or light absorbing material, and/or an optical matching material. Examples of optical material 750 include an optical scattering material, such as an optical adhesive filled with nanometer to micrometer sized particles; or an optical absorbing material, such as a material that contains carbon black; or an optical matching material, such as an index matching optical adhesive. In examples, optical material 750 may have a substantially uniform optical response (transmission, scattering, absorption) in an optical wavelength range of 400 nm to 800 nm. In other examples, optical material 750 may have a varying optical response in an optical wavelength range of 400 nm to 800 nm.

In the depicted example, optical material 750 extends across (or over) gap 708 between adjacent display tiles 700, 700. In examples, optical material 750 includes a cover glass or a layer of polymer material extended over light sources 720 of adjacent display tiles 700, 700 such that optical material 750 contacts first surface 712 of adjacent display tiles 700, 700. Examples of the cover glass include ion exchanged glass, chemically strengthened glass, such as Corning® Gorilla® glass from Corning Incorporated, soda lime glass, drawn or rolled or float glass sheet, or alkali-free glass.

As schematically depicted in the example of FIG. 7, with optical blurring of seam 706 by optical element 740, including optical material 750, light from an external source, such as ambient light 792, is scattered and/or absorbed at seam 706 including, more specifically, at gap 708 between adjacent display tiles 700, 700. In addition, light from an internal source, such as light 722 from a light source 720, is scattered and/or absorbed at seam 706 including, more specifically, at gap 708 between adjacent display tiles 700, 700. By scattering and/or absorbing light at seam 706 including, more specifically, at gap 708 between adjacent display tiles 700, 700, optical defects resulting from seam 706 including, more specifically, from gap 708 between adjacent display tiles 700, 700 may be minimized or eliminated. Specifically, ambient light or light produced from light sources 720 may be reflected or transmitted similarly at seam 706, including from gap 708, as compared to display tiles 700, 700. As such, in examples, optical element 740 may provide optical matching between adjacent display tiles 700, 700.

FIG. 8 schematically depicts a side view of an example of adjacent display tiles 800, 800 with an optically blurred seam. More specifically, as depicted in the example of FIG. 8, display tiles 800, 800, each as examples of display tile 100, include a substrate 810 having a first surface 812 and a second surface 814 opposite first surface 812, with light sources 820 provided on first surface 812 and control electronics, such as control electronics 130 (FIG. 1 B), provided on second surface 814. In other examples, light sources 820 and/or control electronics may be provided on other surfaces. In the depicted example, display tiles 800, 800 are arranged next to each other such that a seam 806 exists between display tiles 800, 800. In examples, a gap 808 may exist at seam 806 between adjacent display tiles 800, 800. As such, in examples, seam 806 includes gap 808 between adjacent display tiles 800, 800.

In one example, as depicted in FIG. 8, seam 806 including, more specifically, gap 808 between adjacent display tiles 800, 800, is optically blurred by an optical element 840 at seam 806 including, more specifically, at gap 808 between adjacent display tiles 800, 800. Optical element 840 optically blurs seam 806 between adjacent display tiles 800, 800, for example, by scattering and/or absorbing light at seam 806. As such, in examples, optical element 840 optically blends or disperses light from and/or at seam 806. In addition, in examples, optical element 840 may provide optical matching between adjacent display tiles 800, 800. In the depicted example, optical element 840 is across gap 808 between adjacent display tiles 800, 800.

In examples, optical element 840 includes optical material 850 at seam 806 including, more specifically, across gap 808 between adjacent display tiles 800, 800. Optical material 850 may include, for example, an optical or light scattering material, an optical or light absorbing material, and/or an optical matching material. Examples of optical material 850 include an optical scattering material, such as an optical adhesive filled with nanometer to micrometer sized particles; or an optical absorbing material, such as a material that contains carbon black; or an optical matching material, such as an index matching optical adhesive. In examples, optical material 850 may have a substantially uniform optical response (transmission, scattering, absorption) in an optical wavelength range of 400 nm to 800 nm. In other examples, optical material 850 may have a varying optical response in an optical wavelength range of 400 nm to 800 nm.

In the depicted example, optical material 850 extends across (or over) gap 808 between adjacent display tiles 800, 800. In examples, optical material 850 includes a cover glass or a layer of polymer material extended over light sources 820 of adjacent display tiles 800, 800 such that optical material 850 contacts first surface 812 of adjacent display tiles 800, 800. Examples of the cover glass include ion exchanged glass, chemically strengthened glass, such as Corning® Gorilla® glass from Corning Incorporated, soda lime glass, drawn or rolled or float glass sheet, or alkali-free glass.

In examples, optical element 840 includes optical features 860 at seam 806 including, more specifically, across gap 808 between adjacent display tiles 800, 800. Optical features 860 may include, for example, optical or light scattering features and/or optical or light absorbing features. Examples of optical features 860 include roughness, prisms, lenticulars, or other physical structures. Optical features 860 may be provided, for example, at or on a surface or interface of optical element 840 or within its bulk.

In the depicted example, optical features 860 are supported by optical material 850 at seam 806. More specifically, in the depicted example, optical features 860 are supported by optical material 850 as provided across (or over) gap 808 between adjacent display tiles 800, 800. As such, optical features 860 are provided across (or at) gap 808 between adjacent display tiles 800, 800. In examples, optical features 860 include optical features 862 supported by optical material 850 on one side of optical material 850 and optical features 864 supported by optical material 850 on an opposite side of optical material 850. Optical features 862 and optical features 864 may include the same or different features. In examples, optical features 862 include a specular reflector (or reflectors), whereby reflection is off of a smooth surface such that incident light remains concentrated upon reflection, and optical features 864 include a diffuse reflector (or reflectors), whereby reflection is off of a rough surface such that incident light is dispersed in many directions upon reflection. As such, in examples, optical features 862 reflect light to optical features 864 whereby optical features 864 scatter the reflected light.

As schematically depicted in the example of FIG. 8, with optical blurring of seam 806 by optical element 840, including optical material 850 and/or optical features 860, light from an internal source, such as light 822 from a light source 820, is scattered and/or absorbed at seam 806 including, more specifically, at gap 808 between adjacent display tiles 800, 800. By scattering and/or absorbing light at seam 806 including, more specifically, at gap 808 between adjacent display tiles 800, 800, optical defects resulting from seam 806 including, more specifically, from gap 808 between adjacent display tiles 800, 800 may be minimized or eliminated. Specifically, ambient light or light produced from light sources 820 may be reflected or transmitted similarly at seam 806, including from gap 808, as compared to display tiles 800, 800. As such, in examples, optical element 840 may provide optical matching between adjacent display tiles 800, 800.

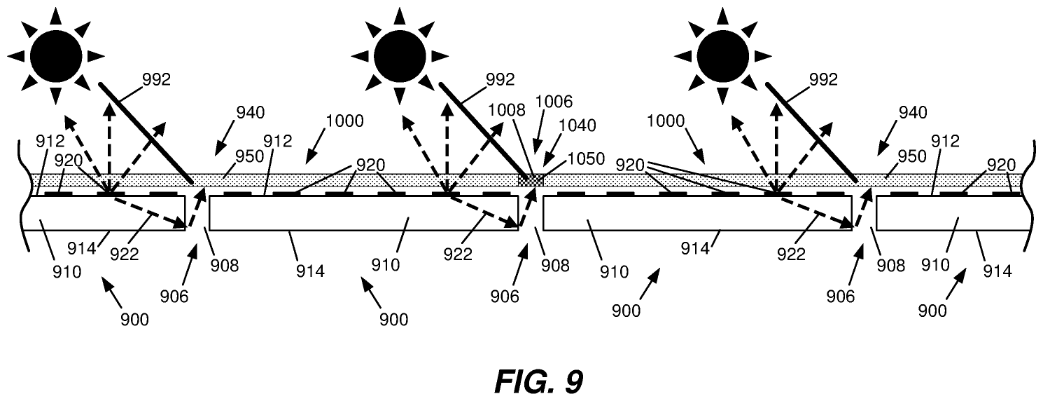

FIG. 9 schematically depicts a side view of an example of adjacent display tiles 900, 900, 900, 900 with an optically blurred seam. More specifically, as depicted in the example of FIG. 9, display tiles 900, 900, 900, 900, each as examples of display tile 100, include a substrate 910 having a first surface 912 and a second surface 914 opposite first surface 912, with light sources 920 provided on first surface 912 and control electronics, such as control electronics 130 (FIG. 1B), provided on second surface 914. In other examples, light sources 920 and/or control electronics may be provided on other surfaces. In the depicted example, display tiles 900, 900, 900, 900 are arranged next to each other such that a seam 906 exists between adjacent display tiles 900, 900. In examples, a gap 908 may exist at seam 906 between adjacent display tiles 900, 900. As such, in examples, seam 906 includes gap 908 between adjacent display tiles 900, 900.

In one example, as depicted in FIG. 9, seam 906 including, more specifically, gap 908 between adjacent display tiles 900, 900, is optically blurred by an optical element 940 at seam 906 including, more specifically, at gap 908 between adjacent display tiles 900, 900. Optical element 940 optically blurs seam 906 between adjacent display tiles 900, 900, for example, by scattering and/or absorbing light at seam 906. As such, in examples, optical element 940 optically blends or disperses light from and/or at seam 906. In addition, in examples, optical element 940 may provide optical matching between adjacent display tiles 900, 900. In the depicted example, optical element 940 is across gap 908 between adjacent display tiles 900, 900.

In examples, optical element 940 includes optical material 950 at seam 906 including, more specifically, across gap 908 between adjacent display tiles 900, 900. Optical material 950 may include, for example, an optical or light scattering material, an optical or light absorbing material, and/or an optical matching material. Examples of optical material 950 include an optical scattering material, such as an optical adhesive filled with nanometer to micrometer sized particles; or an optical absorbing material, such as a material that contains carbon black; or an optical matching material, such as an index matching optical adhesive. In examples, optical material 950 may have a substantially uniform optical response (transmission, scattering, absorption) in an optical wavelength range of 400 nm to 800 nm. In other examples, optical material 950 may have a varying optical response in an optical wavelength range of 400 nm to 800 nm.

In the depicted example, optical material 950 extends across (or over) gap 908 between adjacent display tiles 900, 900. In examples, optical material 950 includes a cover glass or a layer of polymer material extended over light sources 920 of adjacent display tiles 900, 900 such that optical material 950 is spaced from first surface 912 of adjacent display tiles 900, 900. Examples of the cover glass include ion exchanged glass, chemically strengthened glass, such as Corning® Gorilla® glass from Corning Incorporated, soda lime glass, drawn or rolled or float glass sheet, or alkali-free glass.

As schematically depicted in the example of FIG. 9, with optical blurring of seam 906 by optical element 940, including optical material 950, light from an external source, such as ambient light 992, is scattered and/or absorbed at seam 906 including, more specifically, at gap 908 between adjacent display tiles 900, 900. In addition, light from an internal source, such as light 922 from a light source 920, is scattered and/or absorbed at seam 906 including, more specifically, at gap 908 between adjacent display tiles 900, 900. By scattering and/or absorbing light at seam 906 including, more specifically, at gap 908 between adjacent display tiles 900, 900, optical defects resulting from seam 906 including, more specifically, from gap 908 between adjacent display tiles 900, 900 may be minimized or eliminated. Specifically, ambient light or light produced from light sources 920 may be reflected or transmitted similarly at seam 906, including from gap 908, as compared to display tiles 900, 900. As such, in examples, optical element 940 may provide optical matching between adjacent display tiles 900, 900.

In the example of FIG. 9, optical material 950 includes tiles 1000 of the cover glass or layer of polymer material. In the depicted example, tiles 1000, 1000 each extend over multiple display tiles 900, 900, and are arranged next to each other such that a seam 1006 exists between adjacent tiles 1000, 1000. In examples, a gap 1008 may exist at seam 1006 between adjacent tiles 1000, 1000. As such, in examples, seam 1006 includes gap 1008 between adjacent tiles 1000, 1000.

In one example, as depicted in FIG. 9, seam 1006 including, more specifically, gap 1008 between adjacent tiles 1000, 1000, is optically blurred by an optical element 1040 at seam 1006 including, more specifically, at gap 1008 between adjacent tiles 1000, 1000. Optical element 1040 optically blurs seam 1006 between adjacent tiles 1000, 1000, for example, by scattering and/or absorbing light at seam 1006. As such, in examples, optical element 1040 optically blends or disperses light from and/or at seam 1006. In addition, in examples, optical element 1040 may provide optical matching between adjacent tiles 1000, 1000. In the depicted example, optical element 1040 is within gap 1008 between adjacent tiles 1000, 1000.

In examples, optical element 1040 includes optical material 1050 at seam 1006 including, more specifically, within gap 1008 between adjacent tiles 1000, 1000. Optical material 1050 may include, for example, an optical or light scattering material, an optical or light absorbing material, and/or an optical matching material. Examples of optical material 1050 include an optical scattering material, such as an optical adhesive filled with nanometer to micrometer sized particles; or an optical absorbing material, such as a material that contains carbon black; or an optical matching material, such as an index matching optical adhesive. In examples, optical material 1050 may have a substantially uniform optical response (transmission, scattering, absorption) in an optical wavelength range of 400 nm to 800 nm. In other examples, optical material 1050 may have a varying optical response in an optical wavelength range of 400 nm to 800 nm.

In the depicted example, optical material 1050 substantially fills gap 1008 between adjacent tiles 1000, 1000. More specifically, in the depicted example, optical material 1050 contacts and extends between adjacent tiles 1000, 1000 so as to occupy substantially all the space between adjacent tiles

As schematically depicted in the example of FIG. 9, with optical blurring of seam 1006 by optical element 1040, including optical material 1050, light from an external source, such as ambient light 992, is scattered and/or absorbed at seam 1006 including, more specifically, at gap 1008 between adjacent tiles 1000, 1000. In addition, light from an internal source, such as light 922 from a light source 920, is scattered and/or absorbed at seam 1006 including, more specifically, at gap 1008 between adjacent tiles 1000, 1000. By scattering and/or absorbing light at seam 1006 including, more specifically, at gap 1008 between adjacent tiles 1000, 1000, optical defects resulting from seam 1006 including, more specifically, from gap 1008 between adjacent tiles 1000, 1000 may be minimized or eliminated. Specifically, ambient light or light produced from light sources 920 may be reflected or transmitted similarly at seam 1006, including from gap 1008, as compared to tiles 1000, 1000. As such, in examples, optical element 1040 may provide optical matching between adjacent tiles 1000, 1000.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein.

1. A display device, comprising:
at least two adjacent display tiles having a seam therebetween, each of the adjacent display tiles comprising a substrate, one or more light sources on a first surface of the substrate, and control electronics on a second surface of the substrate opposite the first surface; and
an optical element at the seam to optically blur the seam between the adjacent display tiles.

2. The display device of claim 1, wherein the seam between the adjacent display tiles further comprises a gap between the adjacent display tiles.

3. The display device of claim 1, wherein the optical element scatters light at the seam between the adjacent display tiles.

4. The display device of claim 1, wherein the optical element absorbs light at the seam between the adjacent display tiles.

5. The display device of claim 1, wherein the optical element comprises optical material at the seam.

6.-7. (canceled)

8. The display device of claim 5, wherein the seam between the adjacent display tiles further comprises a gap between the adjacent display tiles and wherein the optical material substantially fills the gap.

9. (canceled)

10. The display device of claim 5, wherein the optical material extends over the one or more light sources of at least one of the adjacent display tiles.

11.-12. (canceled)

13. The display device of claim 5, wherein the optical element further comprises optical features supported by the optical material.

14. (canceled)

15. The display device of claim 1, wherein the optical element comprises optical features at the seam.

16.-20. (canceled)

21. A method of making a display device, comprising:
positioning at least two display tiles adjacent to each other with a seam therebetween, each of the adjacent display tiles comprising a substrate, one or more light sources on a first surface of the substrate, and control electronics on a second surface of the substrate opposite the first surface; and
including an optical element at the seam to optically blur the seam between the adjacent display tiles.

22. The method of claim 21, wherein positioning the at least two display tiles adjacent to each other further comprises positioning the at least two display tiles adjacent to each other with a gap therebetween.

23. The method of claim 21, wherein the optical element scatters light at the seam between the adjacent display tiles.

24. The method of claim 21, wherein the optical element absorbs light at the seam between the adjacent display tiles.

25. The method of claim 21, wherein including the optical element comprises including optical material at the seam.

26.-27. (canceled)

28. The method of claim 25, wherein the seam between the adjacent display tiles further comprises a gap between the adjacent display tiles and wherein the optical material substantially fills the gap.

29. (canceled)

30. The method of claim 25, wherein including the optical material comprises extending the optical material over the one or more light sources of at least one of the adjacent display tiles.

31.-32. (canceled)

33. The method of claim 25, wherein including the optical material comprises supporting optical features with the optical material.

34. (canceled)

35. The method of claim 21, wherein including the optical element comprises including optical features at the seam.

36.-40. (canceled)
